(19) United States
(12) Patent Application Publication
(10) Pub. No.: US 2012/0241196 A1
(43) Pub. Date: Sep. 27, 2012

(54) CIRCUIT BOARD AND METHOD OF MANUFACTURING SAME

(75) Inventor: TAO WANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/327,778

(22) Filed: Dec. 16, 2011

(30) Foreign Application Priority Data
Mar. 22, 2011 (CN) 201110069063.9

(51) Int. Cl. H05K 1/00; H05K 3/06

(52) U.S. Cl. 174/250; 29/847

(57) ABSTRACT

A circuit board includes a substrate and a conductor layer disposed on the substrate. The conductor layer includes conducting wires and gapped electrostatic protected areas (EPAs) forming a reticulated pattern and electrically isolated from the conducting wires. The manner and method of construction of the circuit board reduces warping and bulging, to induce more reliable component connections. A method for manufacturing the circuit board is also provided.

### BACKGROUND

1. Technical Field

The present disclosure generally relates to circuit boards such as printed circuit boards (PCBs), and to methods of manufacturing circuit boards such as PCBs.

2. Description of Related Art

Circuit boards are used in electronic products as a connection medium connecting electronic components. In manufacturing, the electronic components are usually soldered to a circuit board in a reflow oven at a high temperature. However, warping and bulging may occur on a PCB when the PCB is processed in the reflow oven. The warping of a PCB may result in weak and unreliable electrical connections between the electronic components disposed on the PCB. Therefore, the quality and performance of an electronic component on the PCB may be compromised due to the warping and bulging.

What is needed, therefore, is a circuit board which can overcome the described limitations, and a method of manufacturing such a circuit board.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout the several views, and all the views are schematic.

FIG. 1 is a cross-sectional view of part of a circuit board according to one embodiment, the circuit board including a conductor layer and an insulating layer disposed on the conductor layer.

FIG. 2 is a plan view of the whole conductor layer partly shown in FIG. 1, according to one embodiment.

FIG. 3 is an enlarged view of the circled part III of the conductor layer of FIG. 2.

FIG. 4 is a plan view of the whole insulating layer partly shown in FIG. 1.

FIG. 5 is similar to FIG. 2, but showing a whole conductor layer according to another embodiment.

FIG. 6 is a flowchart of an exemplary method of manufacturing the circuit board of FIG. 1.

FIGS. 7-9 are cross-sectional views showing some successive stages of the method of FIG. 6.

### DETAILED DESCRIPTION

Reference will be made to the drawings to describe certain exemplary embodiments in detail.

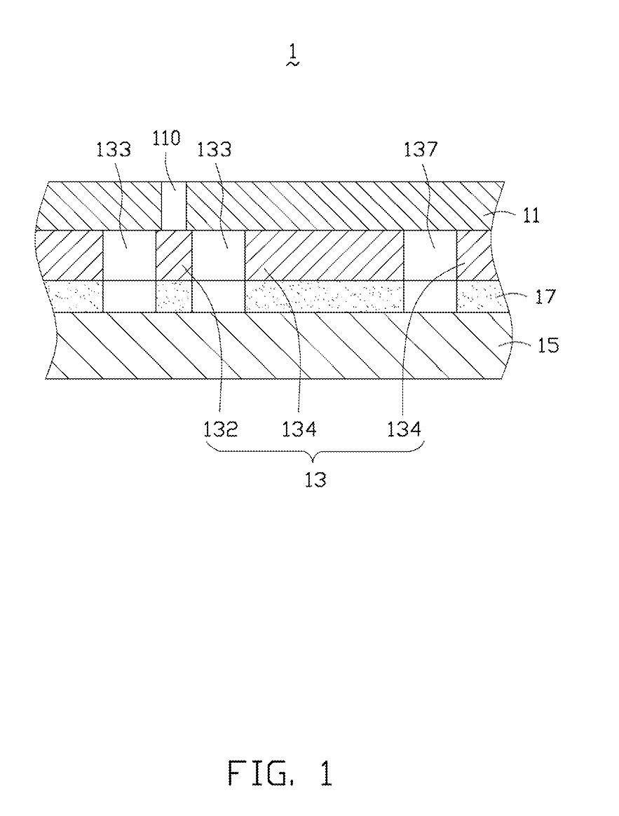

Referring to FIG. 1, a cross-sectional view of part of a circuit board 1 according to one embodiment is shown. The circuit board 1 may be a PCB, and includes, from bottom to top, a substrate 15, a conductor layer 13, and an insulating layer 11. The insulating layer 11 and the substrate 15 may be made of a resinous material. The conductor layer 13 may be made of a metallic material, preferably copper.

In this embodiment, the conductor layer 13 is attached to the substrate 15 by means of an adhesive layer 17. The adhesive layer 17 may be derived from a liquid adhesive applied during manufacturing of the circuit board 1. In an alternative embodiment, the conductor layer 13 can be directly bonded to the substrate 15 without the adhesive layer 17. In another alternative embodiment, the conductor layer 13 and the substrate 15 can be formed as one piece in one process by employing a double molding method.

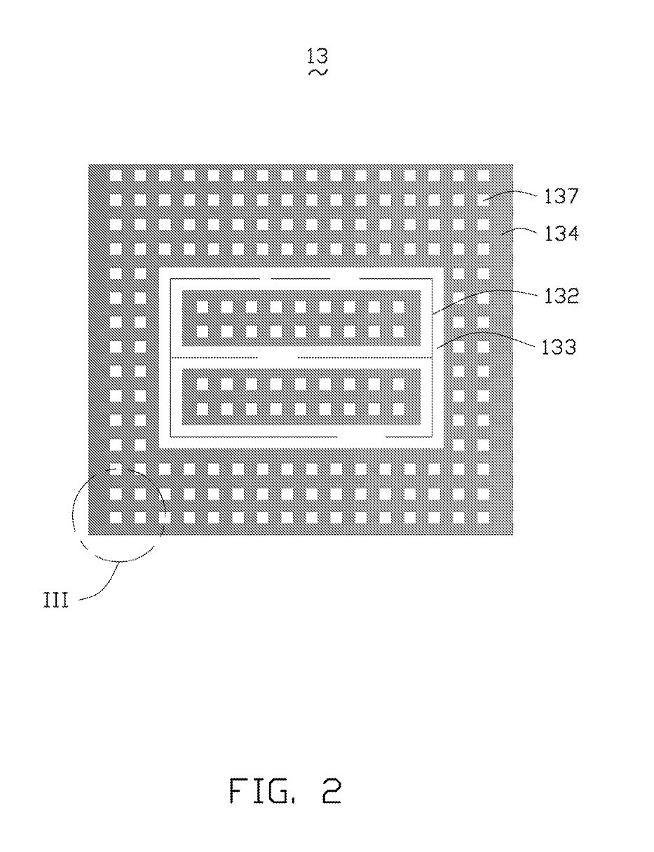

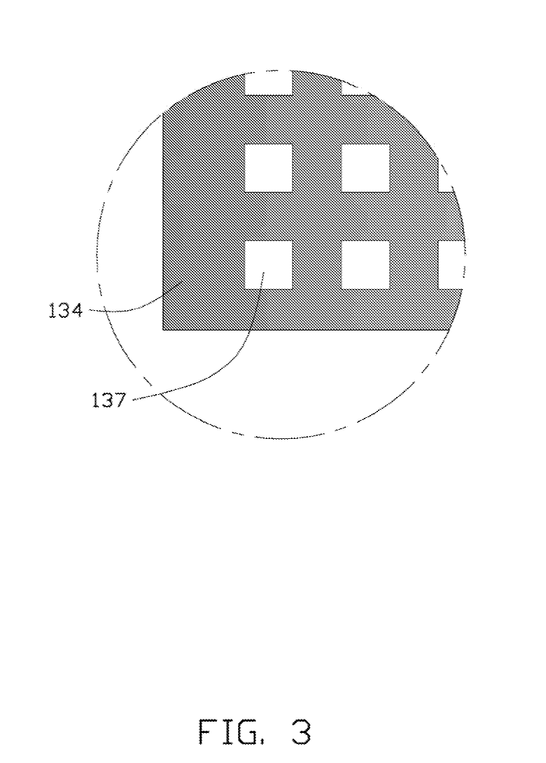

Referring also to FIGS. 2 and 3, the conductor layer 13 includes a plurality of conducting wires or traces (hereinafter, “conducting wires”) 132, and a plurality of electrostatic protected areas (EPAs) 134 physically separated and electrically isolated from the plurality of conducting wires 132. The conducting wires 132 are configured to connect electronic components and realize electronic interconnections between the electronic components. The EPAs 134 are connected to grounding terminals (not shown) of the circuit board 1 to achieve electrostatic protection. The conducting wires 132 and the EPAs 134 are made of the same metallic material, and are formed separately from each other via an etching process. For example, when the conductor layer 13 is made of copper and etched, this forms a plurality of copper wires (or traces) serving as the conducting wires 132, and a plurality of copper foils (or patches) serving as the EPAs 134 and being separate from the copper wires. In particular, first portions of the conductor layer 13 between the copper wires and the copper foils are etched away, and second portions of the adhesive layer 17 corresponding to the first portions are also etched away. Thereby, a plurality of gaps 133 are formed in the conductor layer 13, and prevent the copper wires and the copper foils from being electrically connected. Further, the gaps 133 also extend through the adhesive layer 17. Therefore, parts of the insulating layer 11 can be directly exposed to the substrate 15 via the gaps 133.

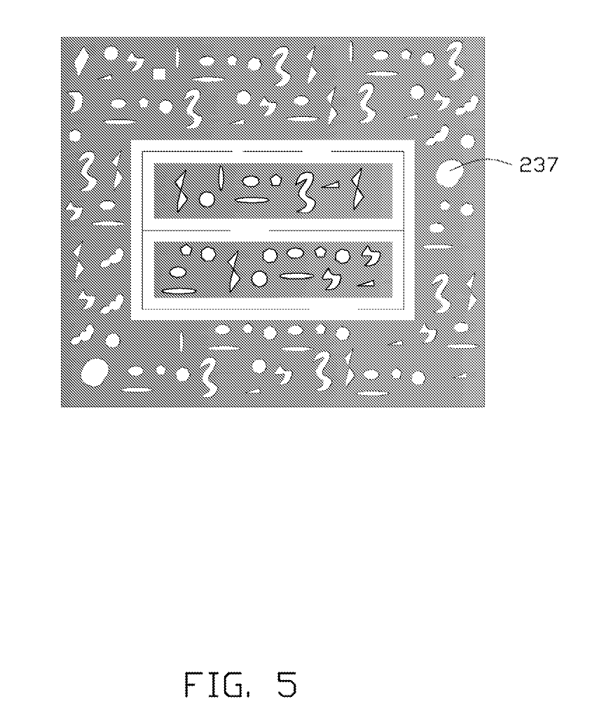

Each EPA 134 includes a plurality of openings 137, with each opening 137 being defined through a thickness of the EPA 134. The openings 137 are arranged in a matrix. Preferably, each opening 137 is rectangular, with a size in the range from 1 mm×1 mm to 3 mm×3 mm. In the illustrated embodiment, each opening 137 is square. A distance separating each two adjacent openings 137 is approximately 1 mm. Further, the openings 137 also extend through the adhesive layer 17. Therefore, parts of the insulating layer 11 can be directly exposed to the substrate 15 via the openings 137. Preferably, the openings 137 do not divide the EPA 134 into separate independent portions. In this way, the interconnecting wires between the EPA 134 and the grounding terminals of the circuit board 1 are simplified. Referring to FIG. 5, in other embodiments, the shapes of openings 237 can be triangular, circular, elliptical, wave-like, diamond-shaped, or of other irregular shape; and such shaped openings 237 can be randomly arranged.

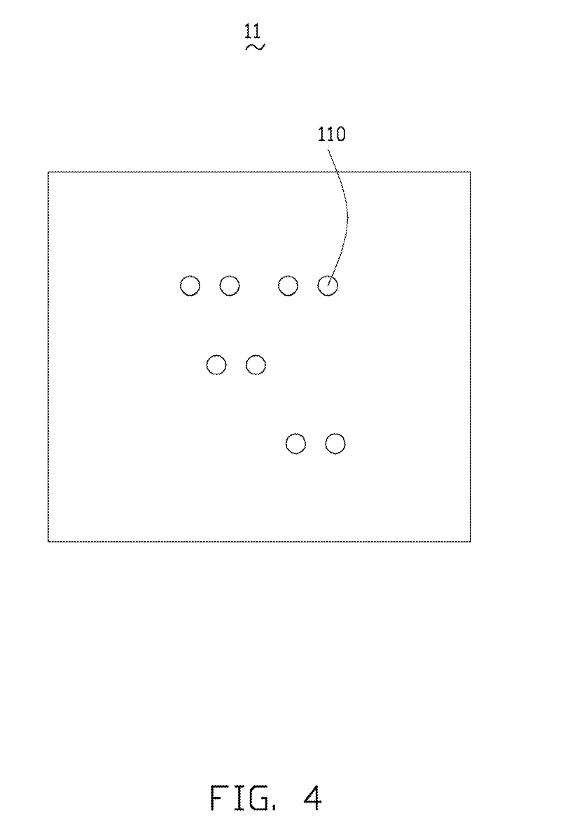

Referring to FIG. 4, the insulating layer 11 includes a plurality of holes 110, with each hole 110 being defined through a thickness of the insulating layer 11. The holes 110 are configured to allow connections between the electronic components and the conducting wires 132 of the conductor layer 13. Preferably, the holes 110 have metallic pads therein, such as copper pads. The metallic pads are electrically connected to certain of the conducting wires 132, and have pins configured to allow the soldering of the electronic components to the conducting wires 132. Therefore, the conducting wires 132 may be connected to the electronic components by means of the metallic pads in the holes 110.

Even under high temperature conditions, the gaps 133 and the openings 137 can provide spaces for any lateral expansion of the EPAs 134 when the conductor layer 13 is heated. Therefore, any warping and bulging in the EPAs 134 is lessened, and the surface of the circuit board 1 can thereby remain flat. Thus, the electronic connections between the electronic components disposed on the circuit board 1 and the conducting wires 132 are firmer and more reliable, and the quality of the circuit board 1 is improved.

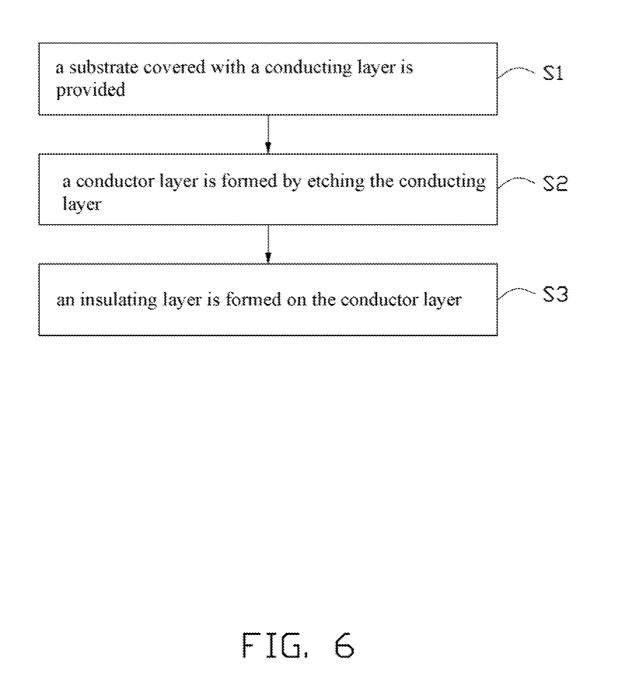

Referring to FIG. 6, a flowchart of an exemplary method of manufacturing the circuit board 1 is shown. The method includes the following steps.

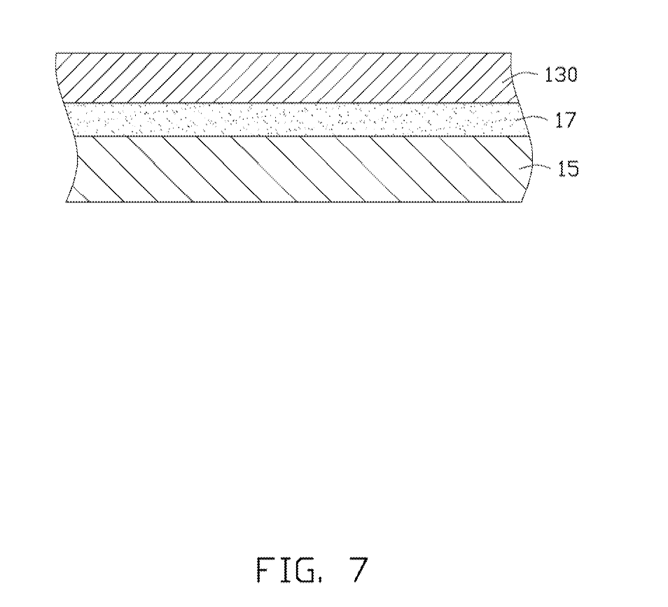

In step S1, referring to FIG. 7, a substrate 15 covered with a conducting layer 130 is provided.

The conducting layer 130 can be attached to the substrate 15 by means of an adhesive layer 17. In an alternative embodiment, the conducting layer 130 can be directly bonded to the substrate 15 without an adhesive layer 17. In another alternative embodiment, the conducting layer 130 and the substrate 15 can be formed as one piece in one process by employing a double molding method. The conducting layer 130 is preferably made of copper.

In step S2, a conductor layer 13 is formed by etching the conducting layer 130.

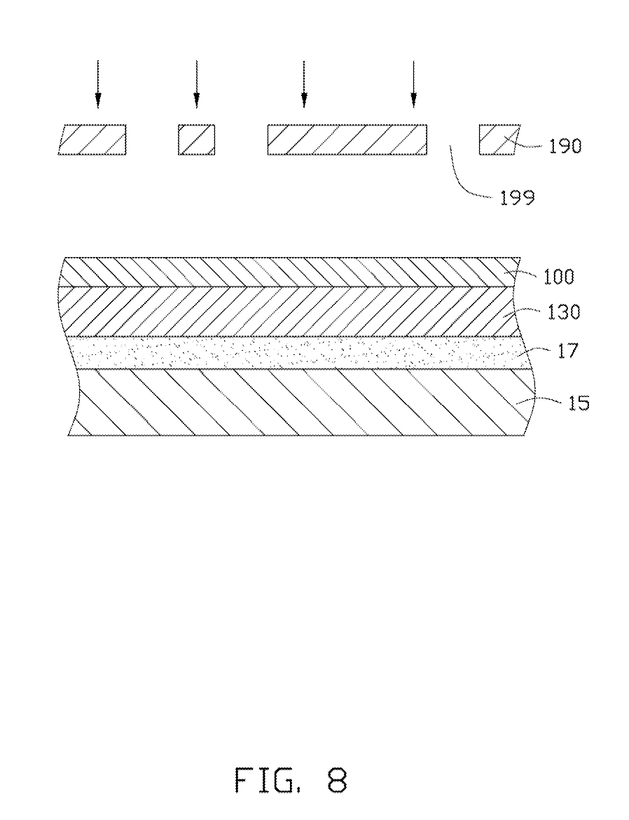

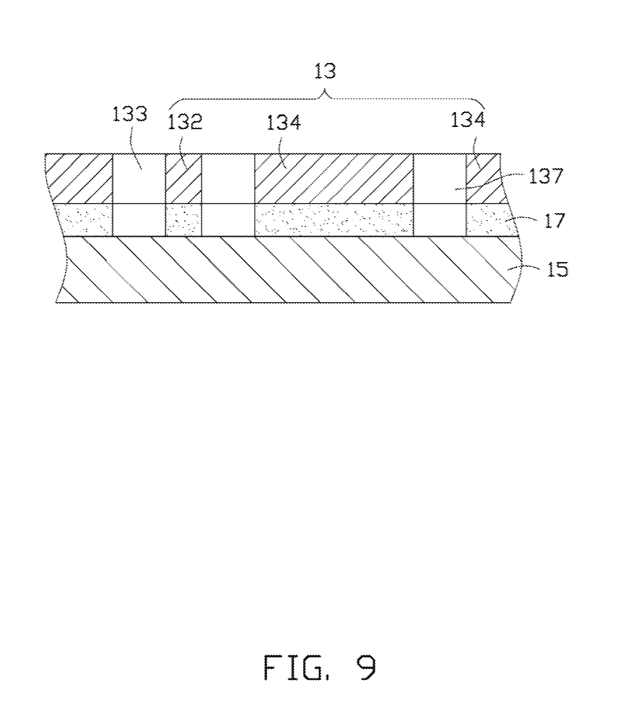

Referring to FIG. 8, a photo resist layer 100 is applied on the conducting layer 130, and a mask 190 is employed to expose and develop the conducting layer 130. The mask 190 includes a plurality of holes 199. Holes (not labeled) are formed in the photo resist layer 100 as a result of the exposure and development of the photo resist layer 100, with the holes being located corresponding to the holes 199. Then the exposed portions of the conducting layer 130 beneath the holes are etched away, whereby the gaps 133 and the openings 137 of the conducting layer 130 are formed. Further, the exposed portions of the adhesive layer 17 below the conducting layer 130 are etched away, whereby the gaps 133 and the openings 137 also extend through the adhesive layer 17. Referring to FIG. 9, the photo resist layer 100 is removed after the etching of the conducting layer 130 and the adhesive layer 17. In an alternative embodiment, the parts of the adhesive layer 17 corresponding to the gaps 133 and the openings 137 can be removed by using other film-removing methods known in the art. Thereby, the conductor layer 13 having the gaps 133 between the conducting wires 132 and the EPAs 134, and having the openings 137 in the EPAs 134, is formed.

In step S3, an insulating layer 11 is formed on the conductor layer 13.

In particular, holes 110 corresponding to the pins of the electronic components are first made in the insulating layer 11, and then the insulating layer 11 having the holes 110 is disposed on the conductor layer 13.

The circuit board 1 as shown in FIG. 1 is finally formed by being heated in a reflow oven, for example. When the circuit board 1 is placed in the reflow oven, the gaps 133 and the openings 137 can provide spaces for any lateral expansion of the EPAs 134 when the conductor layer 13 is heated. Therefore, any warping and bulging in the EPAs 134 is lessened, and the surface of the circuit board 1 can thereby remain flat.

It is believed that the present embodiments and their advantages will be understood from the foregoing description, and it will be apparent that various changes may be made thereto without departing from the spirit and scope of the embodiments or sacrificing all of their material advantages.

What is claimed is:

1. A circuit board comprising:
a substrate; and
a conductor layer disposed on the substrate, the conductor layer comprising a plurality of conducting wires and a plurality of electrostatic protected areas (EPAs) electrically isolated from the plurality of conducting wires, wherein each of the EPAs comprises a plurality of openings.

2. The circuit board of claim 1, wherein the openings are arranged in a matrix.

3. The circuit board of claim 2, wherein each of the openings is square.

4. The circuit board of claim 3, wherein a size of each of the openings is in the range from 1 mm×1 mm to 3 mm×3 mm.

5. The circuit board of claim 3, wherein a distance separating two adjacent openings is approximately 1 mm.

6. The circuit board of claim 1, wherein the conductor layer further comprises a plurality of gaps, the gaps separating the conducting wires from the EPAs.

7. The circuit board of claim 1, further comprising an adhesive layer between the conductor layer and the substrate, the adhesive layer adhering the conductor layer to the substrate.

8. The circuit board of claim 7, wherein the openings pass through the conductor layer and adhesive layer.

9. The circuit board of claim 8, further comprising an insulating layer disposed on the conductor layer, wherein the insulating layer comprises a plurality of holes.

10. The circuit board of claim 9, wherein the holes are configured to allow connection between pins of electronic components disposed on the circuit board and corresponding of the conducting wires of the conductor layer.

11. A method of manufacturing a circuit board, the method comprising:
providing a substrate covered with a conducting layer; and
forming a conductor layer by etching the conducting layer, the conductor layer comprising a plurality of conducting wires, a plurality of electrostatic protected areas (EPAs) electrically isolated from the plurality of conducting wires, and a plurality of openings in each of the EPAs.

12. The method of claim 11, wherein the openings are arranged in a matrix.

13. The method of claim 12, wherein each of the openings is square.

14. The method of claim 13, wherein a size of each of the openings is in the range from 1 mm×1 mm to 3 mm×3 mm.

15. The method of claim 13, wherein a distance separating two adjacent openings is approximately 1 mm.

16. The method of claim 11, further comprising adhering the conducting layer to the substrate via an adhesive layer.

17. The method of claim 16, wherein the openings pass through the conductor layer and adhesive layer.

18. The method of claim 11, further comprising directly bonding the conducting layer to the substrate.

19. The method of claim 11, further comprising providing an insulating layer on the conductor layer.

20. The method of claim 15, further comprising forming a plurality of holes in the insulating layer, wherein the holes are configured to allow connection between pins of electronic components disposed on the circuit board and corresponding of the conducting wires of the conductor layer.
